(19) United States
(12) Patent Application Publication
(10) Pub. No.: US 2025/0343525 A1
(43) Pub. Date: Nov. 6, 2025

(54) RESONATOR DEVICE

(71) Applicant: TXC Corporation, Taipei City (TW)

(72) Inventors: Tzu-Hsiu Peng, Taipei City (TW); Zong-De Lin, Taipei City (TW); Ling-Chieh Shen, Taipei City (TW)

(73) Assignee: TXC Corporation, Taipei City (TW)

(21) Appl. No.: 18/811,780

(22) Filed: Aug. 22, 2024

(30) Foreign Application Priority Data
May 3, 2024 (TW) 113116598

(51) Int. Cl. H03H 9/02; H03H 9/05; H03H 9/13; H03H 9/19

(52) U.S. Cl. CPC H03H 9/02133; H03H 9/02102; H03H 9/0509; H03H 9/132; H03H 9/19

(57) ABSTRACT

A resonator device includes a crystal chip, two metal electrodes, and two groove portions. The crystal chip has a first surface and a second surface opposite to each other, and includes a first area, a second area and a third area. The second area surrounds the first area, and the third area surrounds the second area. The second area is located between the first area and the third area. The two metal electrodes are respectively disposed on the first surface and the second surface. The metal electrode includes a first electrode portion, a connecting portion, and a second electrode portion. The first electrode portion is disposed in the first area. The connecting portion is disposed in the second area. The second electrode portion is disposed in the third area. The connecting portion connects the first electrode portion and the second electrode portion, and the second electrode portion extends to an edge of the crystal chip. The two groove portions are respectively disposed on the first surface and the second surface and are disposed in the second area. A depth of each of the groove portions is equal to a thickness of each of the metal electrodes.

### CROSS-REFERENCE TO RELATED APPLICATION

This application claims the priority benefit of Taiwan application serial no. 113116598, filed on May 3, 2024. The entirety of the above-mentioned patent application is hereby incorporated by reference herein and made a part of this specification.

### BACKGROUND

### Technical Field

The disclosure relates to an electronic element, and more particularly, to a resonator device.

### Description of Related Art

A resonator is an electronic element that utilizes piezoelectric properties of a material and a natural resonance frequency of the material. Quartz is a common material used for the resonator. A quartz element has stable piezoelectric properties and may provide functions such as accurate and wide reference frequencies, clock control, timing function, and noise filtering. In addition, the quartz element may also be used as a sensor for vibration, pressure, etc. and an important optical element.

A working environment where resonator-related products are located is often close to systems such as wireless networks (Wifi) and Bluetooth. A temperature generated by the systems will be transmitted into a vibration area through metal traces of the product, causing thermal stress. As a result, an operating frequency of the product is affected. Especially with product trends of high frequency, high stability, and miniaturization nowadays, an issue of thermal stress cannot be ignored.

Therefore, how to avoid thermal stress concentration and reduce an impact of thermal stress transmitted to the vibration area on vibration characteristics of a chip is one of important issues of research and development in the art.

### SUMMARY

The disclosure provides a resonator device with good vibration characteristics.

A resonator device in the disclosure includes a crystal chip, two metal electrodes, and two groove portions. The crystal chip has a first surface and a second surface opposite to each other and includes a first area, a second area, and a third area. The second area surrounds the first area. The third area surrounds the second area. The second area is located between the first area and the third area. The two metal electrodes are respectively disposed on the first surface and the second surface. Each of the metal electrodes includes a first electrode portion, a connecting portion, and a second electrode portion. The first electrode portion is disposed in the first area. The connecting portion is disposed in the second area. The second electrode portion is disposed in the third area. The connecting portion connects the first electrode portion and the second electrode portion, and the second electrode portion extends to an edge of the crystal chip. The two groove portions are respectively disposed on the first surface and the second surface, and are disposed in the second area. A depth of each of the groove portions is equal to a thickness of each of the metal electrodes.

In an embodiment of the disclosure, the second area is directly adjacent to and completely surrounds the first area. The third area is directly adjacent to and completely surrounds the second area. The first area, the second area, and the third area do not overlap each other.

In an embodiment of the disclosure, the first electrode portion completely covers the first area.

In an embodiment of the disclosure, the first electrode portion is rectangular.

In an embodiment of the disclosure, the first electrode portion has four corner portions, and the corner portions are right angles or rounded corner.

In an embodiment of the disclosure, an area of the connecting portion accounting for an area of the second area is greater than or equal to 1% and less than 100%.

In an embodiment of the disclosure, an area of the connecting portion accounting for an area of the second area is greater than or equal to 5% and less than or equal to 50%.

In an embodiment of the disclosure, an area of the second electrode portion accounting for an area of the third area is greater than or equal to 25%.

In an embodiment of the disclosure, an edge of the third area is aligned with edges of the first surface and the second surface.

In an embodiment of the disclosure, each of the groove portions includes a first section, a second section, a third section, and a fourth section connected to each other in sequence. The first section and the third section extend along a first direction. The second section and the fourth section extend along a second direction perpendicular to the first direction. The first section, the second section, the third section, and the fourth section form multiple bends. The connecting portion is located between the first section and the fourth section to separate the first section and the fourth section.

In an embodiment of the disclosure, the resonator device further includes an opening portion disposed on the first surface and disposed in the third area. A depth of the opening portion is equal to the thickness of each of the metal electrodes.

In an embodiment of the disclosure, the crystal chip has multiple corners, and the opening portion corresponds to at least one of the corners.

In an embodiment of the disclosure, the crystal chip has multiple sides, and the opening portion extends to at least one of the sides.

In an embodiment of the disclosure, the crystal chip has multiple sides, and the second electrode portion extends to at least one of the sides.

In an embodiment of the disclosure, the resonator device further includes at least one conductive adhesive corresponding to the second surface.

Based on the above, in the resonator device according to the disclosure, the upper and lower surfaces of the crystal chip are provided with the metal electrodes surrounding the main vibration area along the edge of the crystal chip, which may avoid thermal stress concentration, reduce the impact of the thermal stress transmitted to the vibration area on the vibration characteristics of the crystal chip, and achieve the purpose of increasing the thermal conductivity to optimize the temperature uniformity and regulating the secondary wave frequency to achieve the chip design with the wide temperature range.

In order for the aforementioned features and advantages of the disclosure to be more comprehensible, embodiments accompanied with drawings are described in detail below.

### BRIEF DESCRIPTION OF THE DRAWINGS

FIG. 1 is a schematic perspective view of a resonator device according to an embodiment of the disclosure.

FIG. 2 is a schematic perspective view of the resonator device in FIG. 1 from another viewing angle.

FIGS. 3A and 3B are schematic front views of the resonator device in FIG. 1.

FIG. 4 is a schematic cross-sectional view of the resonator device in FIG. 1 taken along a line A-A.

FIG. 5 is a schematic cross-sectional view of the resonator device in FIG. 1 taken along a line B-B.

FIGS. 6A and 6B are schematic perspective views of multiple resonator devices according to other embodiments of the disclosure.

FIG. 7A is a schematic perspective view of a resonator device according to an embodiment of the disclosure.

FIG. 7B is a schematic front view of the resonator device in FIG. 7A.

FIG. 8 is a schematic perspective view of a resonator device according to an embodiment of the disclosure.

### DETAILED DESCRIPTION OF DISCLOSED EMBODIMENTS

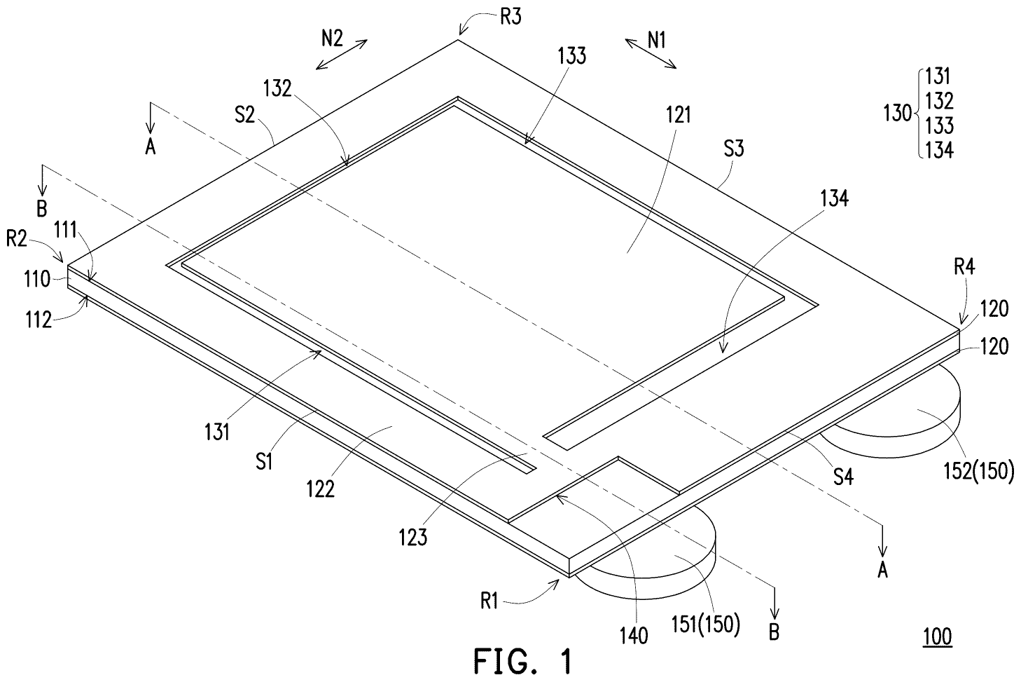

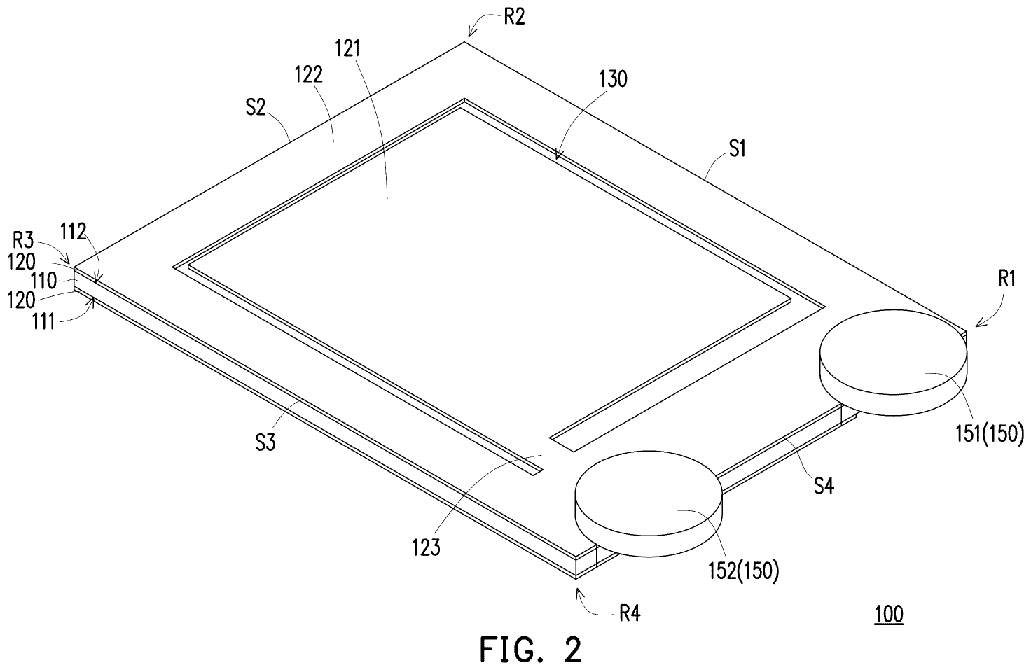

FIG. 1 is a schematic perspective view of a resonator device according to an embodiment of the disclosure. FIG. 2 is a schematic perspective view of the resonator device in FIG. 1 from another viewing angle. FIG. 2, for example, shows the resonator device in FIG. 1 flipped 180 degrees to show a structure therebehind. Referring to FIGS. 1 and 2, a resonator device 100 in this embodiment includes a crystal chip 110, two metal electrodes 120, two groove portions 130, an opening portion 140, and at least one conductive adhesive 150. The crystal chip 110 has a first surface 111 and a second surface 112 opposite to each other. The two metal electrodes 120 are respectively disposed on the first surface 111 and the second surface 112. The two groove portions 130 are respectively disposed on the first surface 111 and the second surface 112. In this embodiment, a material of the crystal chip 110 is a piezoelectric material, such as quartz crystal or other piezoelectric materials.

In an embodiment, the resonator device 100 may further include a base and an upper cover. The crystal chip 110 is disposed on the base through the conductive adhesive 150, and the upper cover is assembled to the base and covers the crystal chip 110. An area between the two metal electrodes 120 is, for example, a vibration area. When a voltage difference is applied between the two metal electrodes 120, the vibration area will be deformed due to an inverse piezoelectric effect. Then, when the voltage difference is removed, the vibration area will vibrate, and due to a piezoelectric effect, a voltage changes between the two metal electrodes 120 with the vibration, so that the two metal electrodes 120 output voltage signals. An operation and implementation of a resonator element may be sufficiently taught, suggested, and implemented by persons with ordinary knowledge in the art, so no further description is incorporated herein.

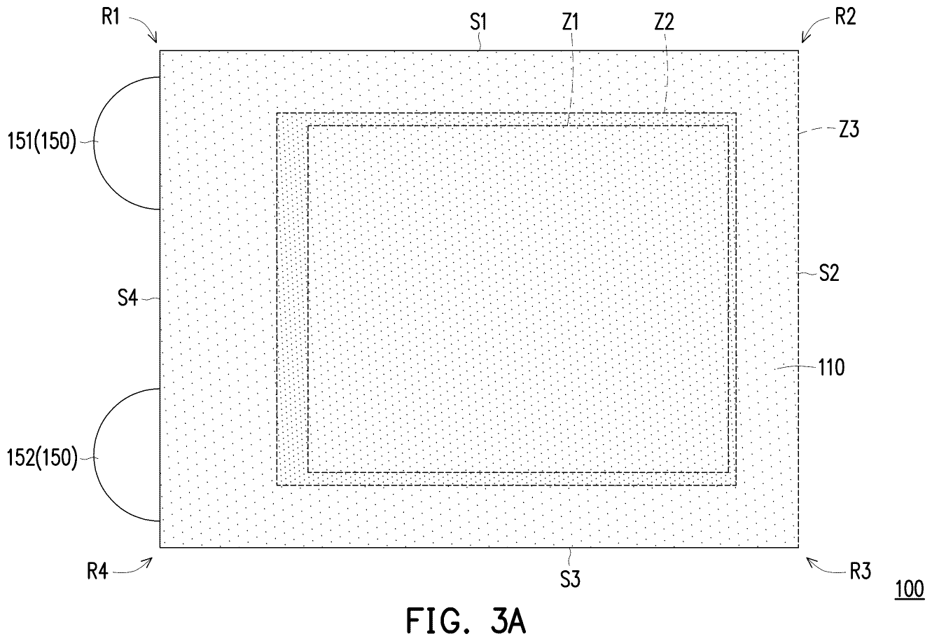

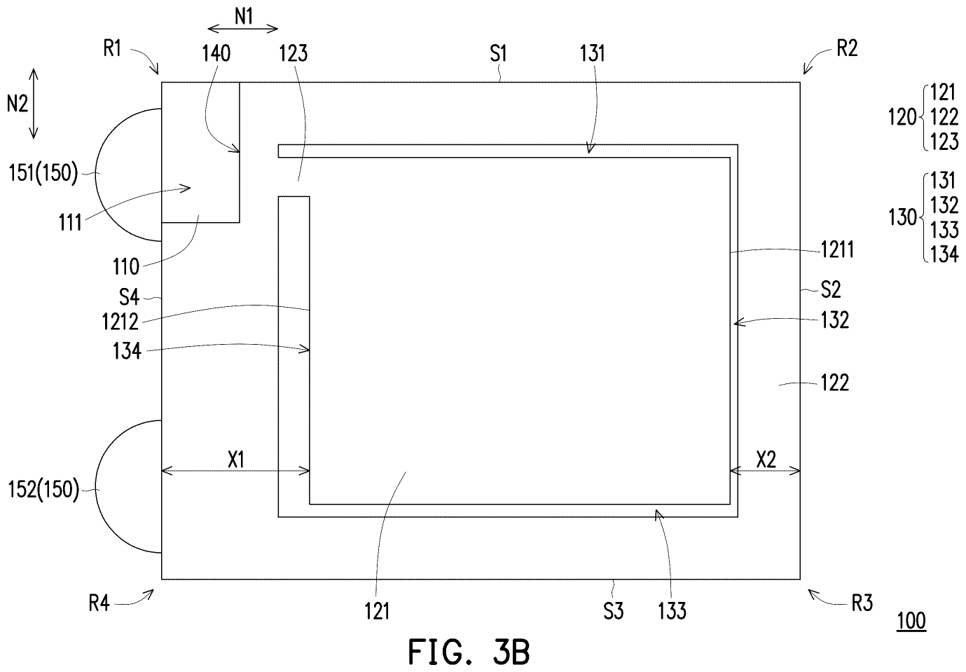

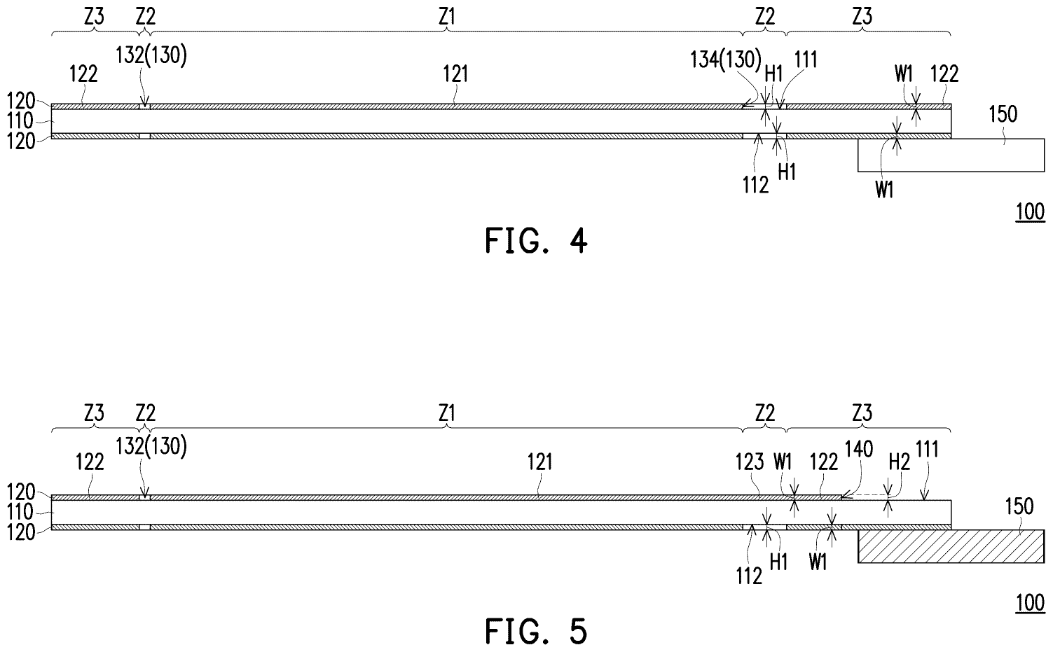

FIGS. 3A and 3B are schematic front views of the resonator device in FIG. 1. FIG. 4 is a schematic cross-sectional view of the resonator device in FIG. 1 taken along a line A-A. FIG. 5 is a schematic cross-sectional view of the resonator device in FIG. 1 taken along a line B-B.

Referring to FIG. 3A first, in this embodiment, the crystal chip 110 includes a first area Z1, a second area Z2, and a third area Z3. The second area Z2 surrounds the first area Z1. The third area Z3 surrounds the second area Z2. The second area Z2 is located between the first area Z1 and the third area Z3. An edge of the third area Z3 is aligned with edges of the first surface 111 and the second surface 112. Specifically, the second area Z2 is directly adjacent to and completely surrounds the first area Z1, the third area Z3 is directly adjacent to and completely surrounds the second area Z2, and the first area Z1, the second area Z2, and the third area Z3 do not overlap each other. It should be noted that in FIG. 3A, the metal electrodes on the crystal chip are omitted and shown with dots of different densities to facilitate display and identification of the first area, the second area, and the third area.

Referring to FIGS. 1, 3A, and 3B, in this embodiment, the metal electrode 120 includes a first electrode portion 121, a connecting portion 123, and a second electrode portion 122. The first electrode portion 121 is disposed in the first area Z1. The connecting portion 123 is disposed in the second area Z2. The second electrode portion 122 is disposed in the third area Z3. The connecting portion 123 connects the first electrode portion 121 and the second electrode portion 122.

In this embodiment, the first electrode portion 121 completely covers the first area Z1. The first electrode portion 121 is, for example, rectangular, but the disclosure is not limited thereto. In this embodiment, the first electrode portion 121 has four corner portions, and the corner portions are right angles. However, in other embodiments, the corner portions may also be rounded corners, and the disclosure is not limited thereto.

In this embodiment, the two groove portions 130 are disposed in the second area Z2. Referring to FIG. 4, a depth H1 of the groove portion 130 is equal to a thickness W1 of each of the metal electrodes 120, so that the first surface 111 and the second surface 112 of the crystal chip 110 are exposed. Referring to FIG. 1, specifically, the groove portion 130 includes a first section 131, a second section 132, a third section 133, and a fourth section 134 connected to each other in sequence. The first section 131 and the third section 133 extend along a first direction N1. The second section 132 and the fourth section 134 extend along a second direction N2. The first section 131, the second section 132, the third section 133, and the fourth section 134 form multiple bends to surround the first electrode portion 121.

In this embodiment, the connecting portion 123 is located between the first section 131 and the fourth section 134 to separate the first section 131 and the fourth section 134. In other embodiments, a shape of the connecting portion 123 may be appropriately adjusted, and the disclosure is not limited thereto. In an embodiment, an area of the connecting portion 123 accounting for an area of the second area Z2 is greater than or equal to 1% and less than 100%, but the disclosure is not limited thereto. In another embodiment, the area of the connecting portion 123 accounting for the area of the second area Z2 is greater than or equal to 5% and less than or equal to 50%, but the disclosure is not limited thereto.

In this embodiment, the second electrode portion 122 extends to an edge of the crystal chip 110. Specifically, the crystal chip 110 has a first side S1, a second side S2, a third side S3, and a fourth side S4. The first side S1 and the third side S3 extend along the first direction N1. The second side S2 and the fourth side S4 extend along the second direction N2 perpendicular to the first direction N1. The second electrode portion 122 extends to the first side S1, the second side S2, the third side S3, and the fourth side S4.

In this embodiment, the opening portion 140 is disposed on the first surface 111 and disposed in the third area Z3. That is to say, the second electrode portion 122 does not completely cover the third area Z3. In fact, the third area Z3 is further provided with the opening portion 140. In an embodiment, an area of the second electrode portion 122 accounting for an area of the third area Z3 is greater than or equal to 25%, but the disclosure is not limited thereto.

Referring to FIG. 5, in this embodiment, a depth H2 of the opening portion 140 is equal to the thickness W1 of each of the metal electrodes 120, so that the first surface 111 of the crystal chip 110 is exposed. In other words, the depth H2 of the opening portion 140 is equal to the depth H1 of the groove portion 130, and the opening portion 140 and the groove portion 130 may be regarded as hollow areas on the crystal chip 110. However, the disclosure is not limited thereto.

Referring to FIG. 3B, in this embodiment, the opening portion 140 extends to the first side S1 and the fourth side S4. For example, the crystal chip 110 has multiple corners R1, R2, R3, and R4. The opening portion 140 corresponds to at least one of the corners, for example, the corner R1, but the disclosure is not limited thereto.

In this embodiment, the conductive adhesive 150 corresponds to the second surface 112 and the fourth side S4, and includes a first colloid 151 and a second colloid 152. The first colloid 151 corresponds to the opening portion 140, but the disclosure is not limited thereto.

In addition, in this embodiment, the first area Z1 corresponds to a center position of the crystal chip 110. The first electrode portion 121 has a first side edge 1211 and a second side edge 1212 respectively corresponding to the second side S2 and the fourth side S4. A first distance X1 between the first side S1 and the first side edge 1211 is greater than a second distance X2 between the second side S2 and the second side edge 1212. That is to say, the first electrode portion 121 is disposed eccentrically and is slightly away from the fourth side S4 provided with the conductive adhesive 150, but the disclosure is not limited thereto.

Under the above configuration, upper and lower surfaces of the crystal chip 110 are provided with a metal layer structure surrounding a main vibration area along the edge of the crystal chip 110 to increase a thermal conduction area for thermal conduction, which may prevent thermal stress from being concentrated in a peripheral area of the crystal chip 110 close to the conductive adhesive 150, reduce an impact of the thermal stress transmitted to the vibration area on vibration characteristics of the crystal chip 100, and achieve a purpose of increasing thermal conductivity to optimize temperature uniformity and regulating a secondary wave frequency to achieve a chip design with a wide temperature range.

Other embodiments are provided below for description. It is noted that some of the reference numerals and descriptions of the above embodiment will apply to the following embodiments. The same reference numerals will represent the same or similar components and the descriptions of the same technical contents will be omitted. Reference may be made to the above embodiment for the omitted descriptions, which will not be repeated in the following embodiments.

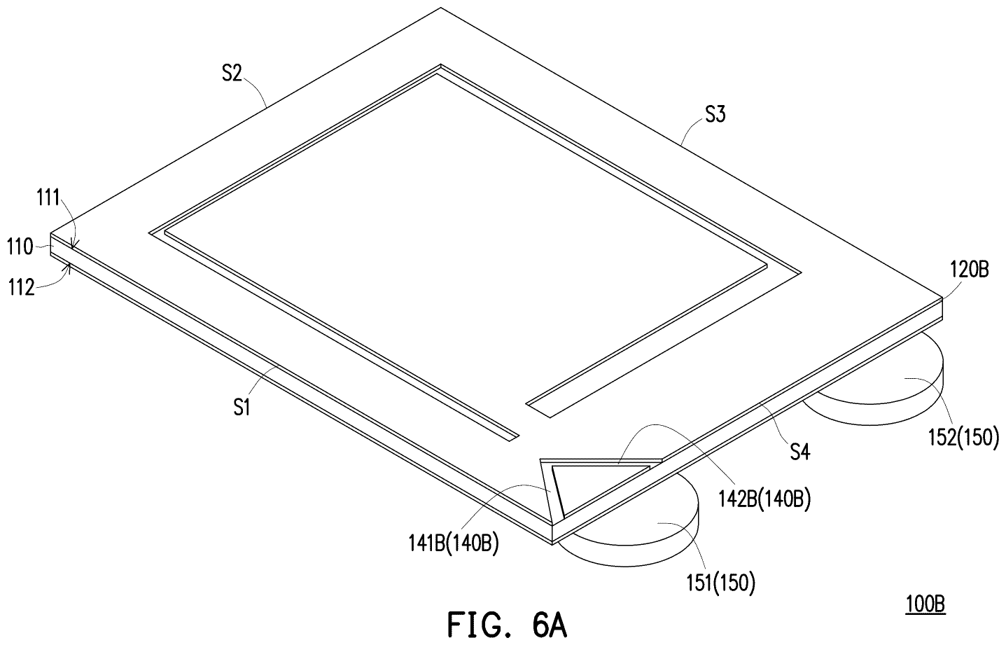

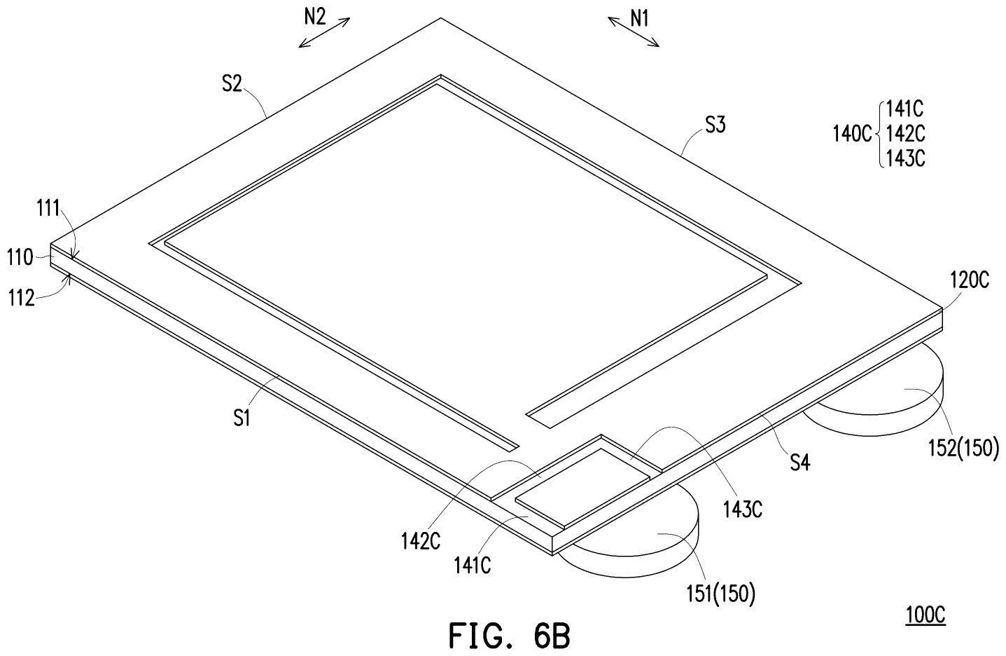

FIGS. 6A and 6B are schematic perspective views of multiple resonator devices according to other embodiments of the disclosure. Referring to FIG. 6A first, in this embodiment, a resonator device 100B is slightly different from the resonator device 100 in FIG. 1. A main difference lies in configurations of a metal electrode 120B and an opening portion 140B.

In FIG. 1, the opening portion 140 is a rectangle, but the disclosure is not limited thereto. In this embodiment, the opening portion 140B is disposed on the first surface 111 and includes a first portion 141B and a second portion 142B connected to each other. The first portion 141B and the second portion 142B have an included angle facing the fourth side S4. The included angle is less than 180 degrees to form a triangle, but the disclosure is not limited thereto. Other portions on the third area Z3 (FIG. 3A) except the opening portion 140B are covered by the metal electrode 120B, but the disclosure is not limited thereto.

Referring to FIG. 6B, in this embodiment, a resonator device 100C is slightly different from the resonator device 100B in FIG. 6A. A main difference lies in configurations of a metal electrode 120C and an opening portion 140C.

In this embodiment, the opening portion 140C is disposed on the first surface 111 and includes a first portion 141C, a second portion 142C, and a third portion 143C connected to each other. The first portion 141C and the third portion 143C are parallel to the first direction N1, and the second portion 142C is parallel to the second direction N2, so as to form a C shape. However, the disclosure is not limited thereto. The other portions on the third area Z3 (FIG. 3A) except the opening portion 140C are covered by the metal electrode 120C, but the disclosure is not limited thereto.

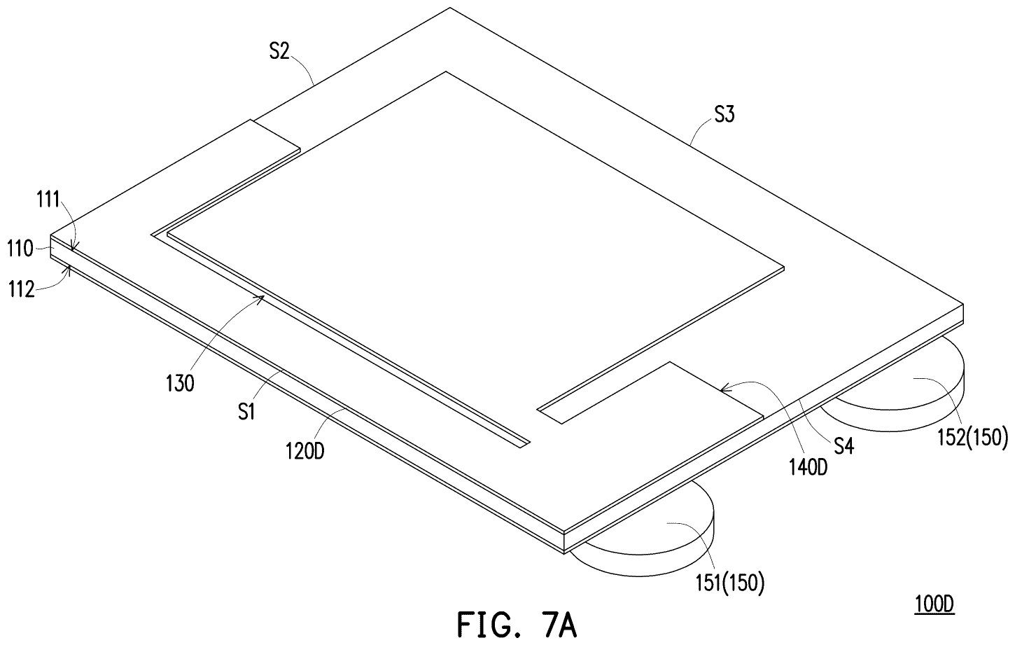

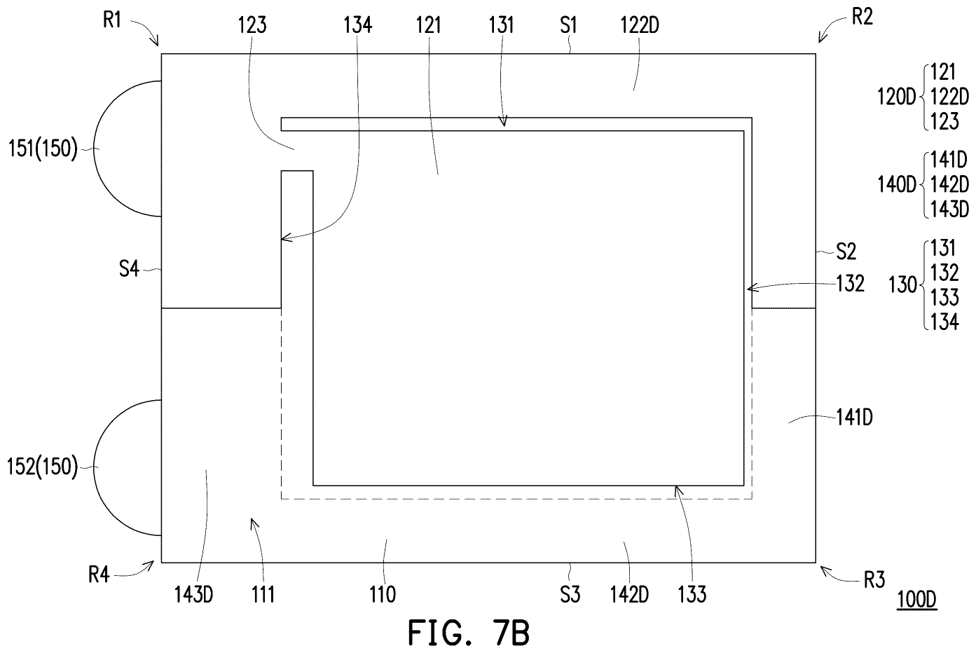

FIG. 7A is a schematic perspective view of a resonator device according to an embodiment of the disclosure. FIG. 7B is a schematic front view of the resonator device in FIG. 7A. Referring to FIGS. 7A and 7B, in this embodiment, a resonator device 100D is slightly different from the resonator device 100 in FIG. 1. A main difference lies in configurations of a metal electrode 120D and an opening portion 140D.

In this embodiment, the opening portion 140D includes a first portion 141D, a second portion 142D, and a third portion 143D connected to each other, which respectively correspond to and extend to the second side S2, the third side S3, and the fourth side S4. Here, the opening portion 140D and the groove portion 130 jointly form the hollow area to expose the crystal chip 110.

In other words, a second electrode portion 122D of the metal electrode 120D extends to the first side S1, the second side S2, and the fourth side S4, and does not extend to the third side S3. That is to say, the second electrode portion 122D is C-shaped, but the disclosure is not limited thereto.

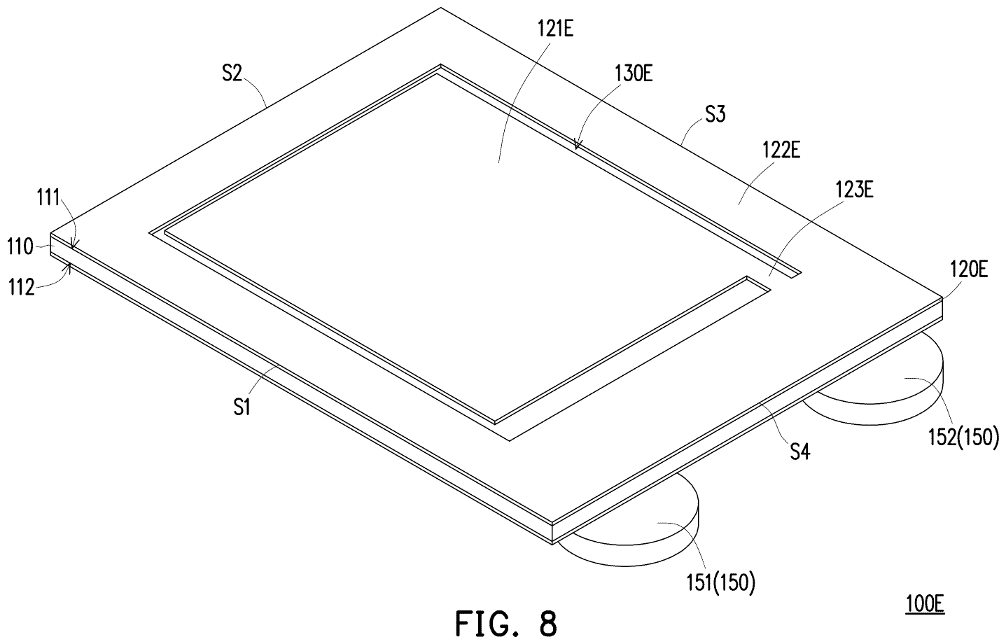

FIG. 8 is a schematic perspective view of a resonator device according to an embodiment of the disclosure. Referring to FIG. 8, in this embodiment, a metal electrode 120E includes a first electrode 121E, a second electrode portion 122E, and a connecting portion 123E. The connecting portion 123E corresponds to the second colloid 152, and other portions on the second area Z2 (FIG. 3A) except the connecting portion 123E are groove portions 130E. The opening portion is omitted in a resonator device 100E, and the second electrode portion 122E is annular. However, the disclosure is not limited thereto.

Based on the above, in the resonator device according to the disclosure, the upper and lower surfaces of the crystal chip are provided with the metal electrodes surrounding the main vibration area along the edge of the crystal chip to increase the thermal conduction area for the thermal conduction, which may prevent the thermal stress from being concentrated in the peripheral area of the crystal chip close to the conductive adhesive, reduce the impact of the thermal stress transmitted to the vibration area on the vibration characteristics of the crystal chip, and achieve the purpose of increasing the thermal conductivity to optimize the temperature uniformity and regulating the secondary wave frequency to achieve the chip design with the wide temperature range.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed description.

What is claimed is:

1. A resonator device, comprising:
a crystal chip having a first surface and a second surface opposite to each other and comprising a first area, a second area, and a third area, wherein the second area surrounds the first area, the third area surrounds the second area, and the second area is located between the first area and the third area;
two metal electrodes respectively disposed on the first surface and the second surface, wherein each of the metal electrodes comprises:
a first electrode portion disposed in the first area;
a connecting portion disposed in the second area; and
a second electrode portion disposed in the third area, wherein the connecting portion connects the first electrode portion and the second electrode portion, and the second electrode portion extends to an edge of the crystal chip; and
two groove portions respectively disposed on the first surface and the second surface, and disposed in the second area, wherein a depth of each of the groove portions is equal to a thickness of each of the metal electrodes.

2. The resonator device according to claim 1, wherein the second area is directly adjacent to and completely surrounds the first area, the third area is directly adjacent to and completely surrounds the second area, and the first area, the second area, and the third area do not overlap each other.

3. The resonator device according to claim 1, wherein the first electrode portion completely covers the first area.

4. The resonator device according to claim 1, wherein the first electrode portion is rectangular.

5. The resonator device according to claim 1, wherein the first electrode portion has four corner portions, and the corner portions are right angles or rounded corners.

6. The resonator device according to claim 1, wherein an area of the connecting portion accounting for an area of the second area is greater than or equal to 1% and less than 100%.

7. The resonator device according to claim 1, wherein an area of the connecting portion accounting for an area of the second area is greater than or equal to 5% and less than or equal to 50%.

8. The resonator device according to claim 1, wherein an area of the second electrode portion accounting for an area of the third area is greater than or equal to 25%.

9. The resonator device according to claim 1, wherein an edge of the third area is aligned with edges of the first surface and the second surface.

10. The resonator device according to claim 1, wherein each of the groove portions comprises a first section, a second section, a third section, and a fourth section connected to each other in sequence, the first section and the third section extend along a first direction, the second section and the fourth section extend along a second direction perpendicular to the first direction, the first section, the second section, the third section, and the fourth section form a plurality of bends, and the connecting portion is located between the first section and the fourth section to separate the first section and the fourth section.

11. The resonator device according to claim 1, further comprising an opening portion disposed on the first surface and disposed in the third area, wherein a depth of the opening portion is equal to the thickness of each of the metal electrodes.

12. The resonator device according to claim 11, wherein the crystal chip has a plurality of corners, and the opening portion corresponds to at least one of the corners.

13. The resonator device according to claim 12, wherein the crystal chip has a plurality of sides, and the opening portion extends to at least one of the sides.

14. The resonator device according to claim 1, wherein the crystal chip has a plurality of sides, and the second electrode portion extends to at least one of the sides.

15. The resonator device according to claim 1, further comprising at least one conductive adhesive corresponding to the second surface.
